(19) United States
(12) Patent Application Publication
(10) Pub. No.: US 2026/0036898 A1
(43) Pub. Date: Feb. 5, 2026

(54) REFLECTIVE MASK BLANK, REFLECTIVE MASK, METHOD OF MANUFACTURING REFLECTIVE MASK BLANK, AND METHOD OF MANUFACTURING REFLECTIVE MASK

(71) Applicant: AGC Inc., Tokyo (JP)

(72) Inventors: Eita NAKANISHI, Tokyo (JP); Daijiro AKAGI, Tokyo (JP)

(73) Assignee: AGC Inc., Tokyo (JP)

(21) Appl. No.: 19/356,372

(22) Filed: Oct. 13, 2025

Related U.S. Application Data
(63) Continuation of application No. PCT/JP2024/017857, filed on May 14, 2024.

(30) Foreign Application Priority Data
May 31, 2023 (JP) 2023-090180

(51) Int. Cl. G03F 1/24; G03F 1/54

(52) U.S. Cl. CPC G03F 1/24; G03F 1/54

(57) ABSTRACT

A reflective mask blank has a substrate, a multi-layer reflective film, a protective film, and an absorbing film, in that order. The absorbing film has a Cr-containing layer consisting of a CrN compound containing 50 at % or more of Cr and 10 at % or more of N. The Cr-containing layer has a full width at half maximum of 1.0° or more of the highest intensity peak in the 20 range of 20° to 50° measured by XRD using CuK α rays, and a rate of a reflectance of EUV light reflected by the multi-layer reflective film and the protective film toward the opposite side of the substrate via the absorbing film is less than 5% of a reflectance of EUV light reflected by the multi-layer reflective film and the protective film toward the opposite side of the substrate without passing through the absorbing film.

The present application is a continuation of PCT/JP2024/017857, filed on May 14, 2024, the entire contents of which are incorporated herein by reference.

### TECHNICAL FIELD

The present disclosure relates to a reflective mask blank, a reflective mask, a method of manufacturing the reflective mask blank, and a method of manufacturing the reflective mask.

### BACKGROUND ART

In recent years, with miniaturization of semiconductor devices, EUV lithography (EUVL), which is an exposure technology using extreme ultraviolet (EUV) light, has been developed. EUV light includes soft X-rays and vacuum ultraviolet light, specifically light with a wavelength of approximately 0.2 nm to 100 nm. At present, EUV with a wavelength of about 13.5 nm is the main focus of research.

In EUVL, a reflective mask is used. The reflective mask has a substrate such as a glass substrate or the like, a multi-layer reflective film that reflects EUV light, a protective film that protects the multi-layer reflective film, and an absorbing film that absorbs EUV light, in that order. The absorbing film not only absorbs EUV light but may also shift the phase of the EUV light. That is, the absorbing film may be a phase shift film. The absorbing film is formed with an opening pattern. In the EUVL, the opening pattern of the absorbing film is transferred to a target substrate such as a semiconductor substrate or the like. The transferring includes reducing and transferring.

A reflective mask blank disclosed in Patent Document 1 includes a substrate, a multi-layer reflective film, a protective film, and an absorbing film in that order. Examples of absorbing films disclosed in Patent Document 1 include:
MoCrRu film (Mo: 20 at %, Cr: 46 at %, Ru: 34 at %),
MoWRu film (Mo: 34 at %, W: 15 at %, Ru: 51 at %),
MoAuRu film (Mo: 13 at %, Au: 12 at %, Ru: 75 at %),
MoWRu film (Mo: 29 at %, W: 6 at %, Ru: 65 at %),
MoWV film (Mo: 46 at %, W: 25 at %, V: 29 at %),
and others.

These absorbing films have a ratio (RA/RB) of 0.05 to 0.25. RA is a reflectance of EUV light reflected by the multi-layer reflective film and the protective film at a side opposite to the substrate via the absorbing film. RB is a reflectance of EUV light reflected by the multi-layer reflective film and the protective film at the side opposite to the substrate without passing through the absorbing film.

A reflective mask blank disclosed in Patent Document 2 includes a substrate, a multi-layer reflective film, a protective film, and a phase shift film, in that order. The phase shift film includes a lower layer and a top layer. In Example 1 of Patent Document 2, the lower layer of the phase shift film is a RuCrN film (Ru: 79.4 at %, Cr: 13.6 at %, N: 7.0 at %, refractive index: 0.900, extinction coefficient: 0.023), and the top layer of the phase shift film is a RuCrO film (Ru: 18.1 at %, Cr: 29.5 at %, O: 52.4 at %, refractive index: 0.931, extinction coefficient: 0.027).

A reflective mask blank disclosed in Patent Document 3 includes a substrate, a multi-layer reflective film, a protective film, and a phase shift film, in that order. In Example 1 of Patent Document 3, the phase shift film is a RuCr film (Ru: 7 at %, Cr: 93 at %, refractive index: 0.929, extinction coefficient: 0.037, relative reflectance: 6%). In addition, in Example 4 of the Patent Document 3, the phase shift film is a RuCr film (Ru: 39 at %, Cr: 61 at %, refractive index: 0.913, extinction coefficient: 0.030, relative reflectance: 15%).

### CITATION LIST

### Patent Document

Patent Document 1: Japanese Unexamined Patent Application, First Publication No. 2022-135928
Patent Document 2: Japanese Unexamined Patent Application, First Publication No. 2021-081644
Patent Document 3: PCT International Publication No. 2019/225736

### SUMMARY OF INVENTION

### Technical Problem

In the related art, a variety of materials are being considered for the absorbing film. A material with Cr as a main component can be considered as a material with a refractive index of 0.920 to 0.940 and an extinction coefficient of 0.032 to 0.044.

An aspect of the present disclosure is directed to providing an absorbing film containing Cr as a main component, which has good amorphous properties and a relative reflectance of less than 5%.

### Solution to Problem

In order to achieve the aforementioned objects, a reflective mask blank according to an aspect of the present disclosure has a substrate, a multi-layer reflective film, a protective film, and an absorbing film, in that order. The multi-layer reflective film reflects EUV light. The protective film protects the multi-layer reflective film during processing of the absorbing film. The absorbing film absorbs the EUV light. The absorbing film has a Cr-containing layer consisting of a CrN compound containing 50 at % or more of Cr and 10 at % or more of N. The Cr-containing layer has a full width at half maximum of 1.0° or more of the highest intensity peak in the 2θ range of 20° to 50° measured by XRD using Cuk α rays, and a rate of reflectance of EUV light reflected by the multi-layer reflective film and the protective film toward a side opposite to the substrate via the absorbing film is less than 5% of the reflectance of EUV light reflected by the multi-layer reflective film and the protective film toward the side opposite to the substrate without passing through the absorbing film.

### Advantageous Effects of Invention

According to the aspect of the present disclosure, it is possible to provide an absorbing film containing Cr as a main component, which has good amorphous properties and a relative reflectance of less than 5%.

### BRIEF DESCRIPTION OF DRAWINGS

FIG. 1 A cross-sectional view showing a reflective mask blank according to an embodiment.

FIG. 2 A flowchart showing a method of manufacturing the reflective mask blank according to the embodiment.

FIG. 3 A cross-sectional view showing a reflective mask according to an embodiment.

FIG. 4 A flowchart showing a method of manufacturing the reflective mask according to the embodiment.

FIG. 5 (A) is a cross-sectional view showing an example of preparing a reflective mask blank, FIG. 5 (B) is a cross-sectional view showing an example upon completion of processing of a hard mask film, and FIG. 5 (C) is a cross-sectional view showing an example upon completion of processing of an absorbing film.

FIG. 6 A cross-sectional view showing an example of EUV light reflected by the reflective mask of FIG. 3.

FIG. 7 A view showing an example of a refractive index and an extinction coefficient of each element.

### DESCRIPTION OF EMBODIMENTS

Hereinafter, an embodiment of the present disclosure will be described with reference to the accompanying drawings. In each drawing, the same or corresponding components are designated by the same reference signs, and description thereof may be omitted. In the specification, “to” indicating a numerical range means that the numbers before and after it are included as the lower and upper limits.

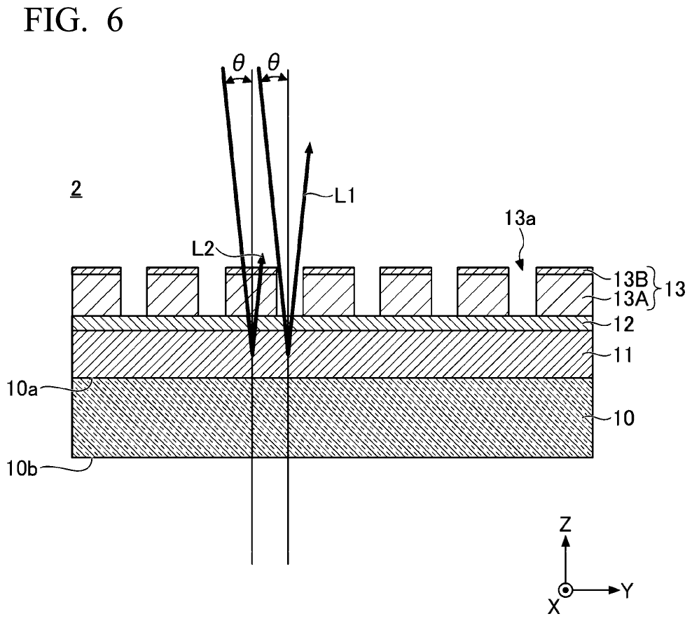

In each drawing, an X-axis direction, a Y-axis direction and a Z-axis direction are directions perpendicular to each other. The Z-axis direction is a direction perpendicular to a first main surface 10a of a substrate 10. The X-axis direction is a direction perpendicular to an incidence surface of EUV light (a surface containing incident light and reflected light). As shown in FIG. 6, the incident light is tilted in a Y-axis positive direction as it moves in a Z-axis negative direction, and the reflected light is tilted in a Y-axis positive direction as it moves in a Z-axis positive direction.

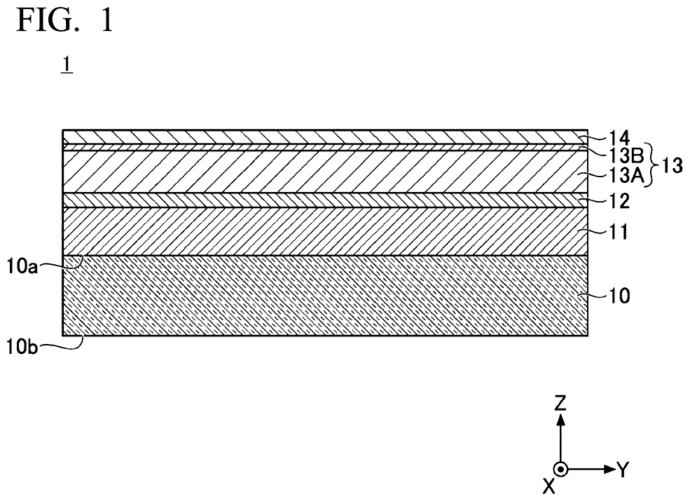

Referring to FIG. 1, a reflective mask blank 1 according to an embodiment will be described. The reflective mask blank 1 has, for example, the substrate 10, a multi-layer reflective film 11, a protective film 12, an absorbing film 13, a hard mask film 14, in that order. The multi-layer reflective film 11, the protective film 12, the absorbing film 13, and the hard mask film 14 are formed on the first main surface 10a of the substrate 10, in that order. The multi-layer reflective film 11 reflects EUV light. The protective film 12 protects the multi-layer reflective film 11 from a first etching gas during processing of the absorbing film 13. The absorbing film 13 absorbs EUV light. The absorbing film 13 may shift a phase of the EUV light without absorbing the EUV light. That is, the absorbing film 13 may be a phase shift film. The hard mask film 14 protects a part of the absorbing film 13 from the first etching gas during processing of the absorbing film 13.

The reflective mask blank 1 may further have a function film, which is not shown in FIG. 1. For example, the reflective mask blank 1 may have a conductive film on the opposite side of the substrate 10 from the multi-layer reflective film 11. The conductive film is formed on a second main surface 10b of the substrate 10. The second main surface 10b is a surface facing opposite to the first main surface 10a. The conductive film is used, for example, to adsorb a reflective mask 2 to an electrostatic chuck of an exposure device. The reflective mask blank 1 may have a diffusion barrier film (not shown) between the multi-layer reflective film 11 and the protective film 12. The diffusion barrier film prevents metal elements contained in the protective film 12 from diffusing into the multi-layer reflective film 11.

While not shown, the reflective mask blank 1 may have a buffer film between the protective film 12 and the absorbing film 13. The buffer film protects the protective film 12 from a first etching gas that forms an opening pattern 13a on the absorbing film 13. The buffer film etches more slowly than the absorbing film 13. Unlike the protective film 12, the buffer film will ultimately have an opening pattern identical to the opening pattern 13a of the absorbing film 13.

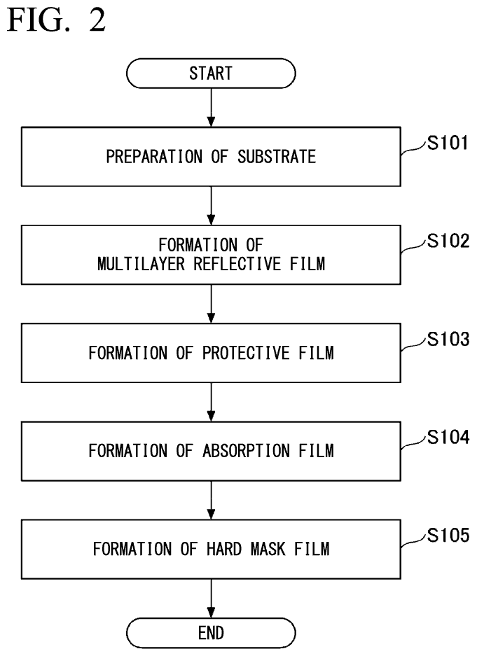

Next, a method of manufacturing the reflective mask blank 1 according to the embodiment will be described with reference to FIG. 2. The method of manufacturing the reflective mask blank 1 has, for example, steps S101 to S105 shown in FIG. 2. In step S101, the substrate 10 is prepared. In step S102, the multi-layer reflective film 11 is formed on the first main surface 10a of the substrate 10. In step S103, the protective film 12 is formed on the multi-layer reflective film 11. In step S104, the absorbing film 13 is formed on the protective film 12. In step S105, the hard mask film 14 is formed on the absorbing film 13. Further, the method of manufacturing the reflective mask blank 1 may further have a step of forming a function film, which is not shown in FIG. 2.

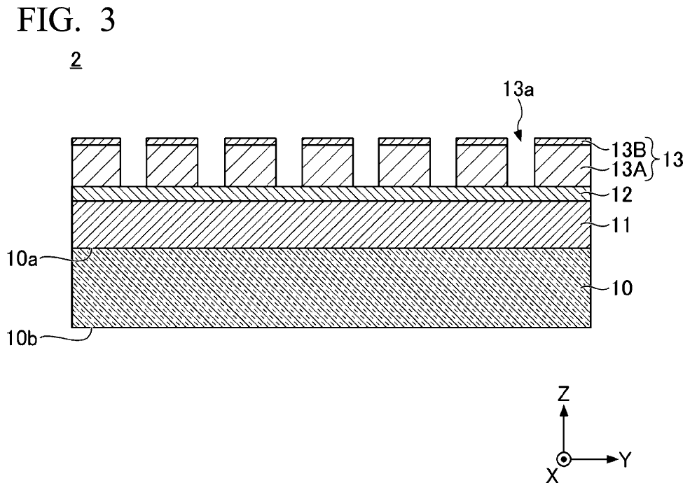

Next, the reflective mask 2 according to the embodiment will be described with reference to FIG. 3. The reflective mask 2 is produced, for example, using the reflective mask blank 1 shown in FIG. 1, and includes the opening pattern 13a in the absorbing film 13. In EUVL, the opening pattern 13a of the absorbing film 13 is transferred to a target substrate such as a semiconductor substrate or the like. Transferring includes reducing and transferring. Further, the hard mask film 14 shown in FIG. 1 is not included in the reflective mask 2.

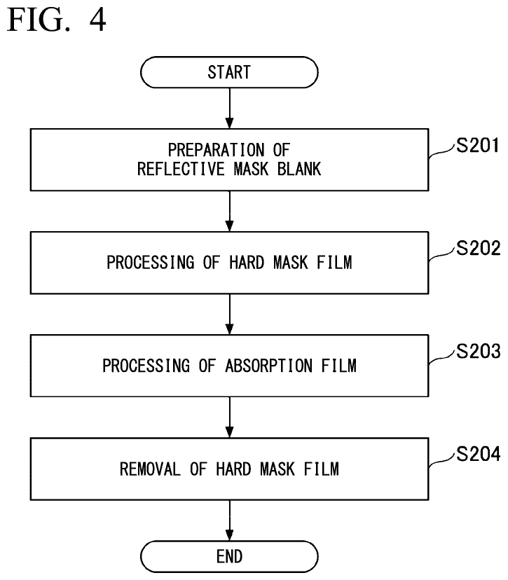

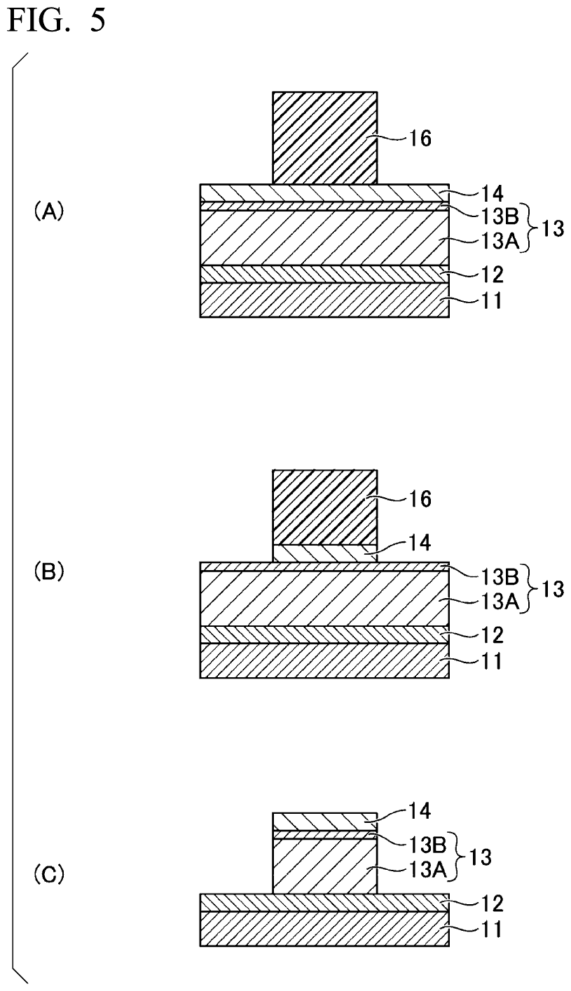

Next, a method of manufacturing the reflective mask 2 according to the embodiment will be described with reference to FIG. 4 and FIG. 5. The method of manufacturing the reflective mask 2 has steps S201 to S204 shown in FIG. 4. In step S201, as shown in FIG. 5 (A), the reflective mask blank 1 is prepared. The reflective mask blank 1 includes a resist film 16 as shown in FIG. 5 (A). The resist film 16 is formed on the hard mask film 14. A predetermined opening pattern transferred to the absorbing film 13 is formed on the resist film 16.

In step S202, as shown in FIG. 5 (B), the hard mask film 14 is processed using the resist film 16 having the opening pattern. In the opening of the resist film 16, the hard mask film 14 is exposed to a second etching gas, which etches the hard mask film 14. Upon completion of step S202, the resist film 16 remains. As a result, the opening pattern of the resist film 16 is transferred to the hard mask film 14.

The second etching gas is selected according to combination of a material of the resist film 16 and a material of the hard mask film 14, and while not particularly limited thereto, for example, includes a fluorine-based gas. The fluorine-based gas includes at least one selected from, for example, CF₄ gas, CHF₃ gas, C₂F₆ gas, C₃F₆ gas, C₄F₆ gas, C₄F₈ gas, CH₂F₂ gas, CH₃F gas, C₃F₈ gas, F₂ gas, SF₆ gas and NF₃ gas. The second etching gas may include an active gas or an inert gas, in addition to the fluorine-based gas. The active gas includes, for example, O₂ gas. The inert gas includes at least one selected from, for example, N₂ gas, He gas and Ar gas. The second etching gas is preferably in the form of plasma.

In step S203, as shown in FIG. 5 (C), the absorbing film 13 is processed using the hard mask film 14 having the opening pattern. In the opening of the hard mask film 14, the absorbing film 13 is exposed to the first etching gas, which etches the absorbing film 13. The hard mask film 14 has a higher resistance to the first etching gas than the absorbing film 13. Upon completion of step S203, the hard mask film 14 remains. As a result, the opening pattern of the hard mask film 14 is transferred to the absorbing film 13.

The first etching gas is selected according to a combination of a material of the hard mask film 14 and a material of the absorbing film 13, and while not particularly limited thereto, for example, includes chlorine-based gas and oxygen-based gas. The chlorine-based gas includes at least one selected from, for example, Cl₂ gas, SiCl₄ gas, CHCl₃ gas, CCl₄ gas and BCl₃ gas. The oxygen-based gas includes at least one selected from, for example, O₂ gas and O₃ gas. The first etching gas may include an inert gas, in addition to the chlorine-based gas and the oxygen-based gas. The inert gas includes at least one selected from, for example, N₂ gas, He gas and Ar gas. The first etching gas is preferably in the form of plasma.

In step S204, while not shown, the hard mask film 14 is removed. To remove the hard mask film 14, for example, a third etching gas is used. The third etching gases include, for example, a fluorine-based gas, like the second etching gas. The third etching gas is preferably in the form of plasma. To remove the hard mask film 14, a chemical solution may be used.

Next, referring to FIG. 1 again, the substrate 10, the multi-layer reflective film 11, the protective film 12, the absorbing film 13, and the hard mask film 14 will be described in that order.

The substrate 10 is, for example, a glass substrate. The material of the substrate 10 is preferably quartz glass containing TiO₂. Compared to common soda lime glass, the quartz glass has a smaller linear expansion coefficient and a smaller dimensional change due to temperature change. The quartz glass may contain 80 mass % to 95 mass % of SiO₂ and 4 mass % to 17 mass % of TiO₂. When the TiO₂ content is 4 mass % to 17 mass %, the linear expansion coefficient is almost zero near room temperature, and almost no dimensional change occurs near room temperature. The quartz glass may contain a third component or impurities other than SiO₂ and TiO₂. Further, the material of the substrate 10 may be crystallized glass, silicon, or metal, etc., deposited from a β-quartz solid solution.

The substrate 10 has the first main surface 10a, and the second main surface 10b opposite to the first main surface 10a. The first main surface 10a is formed with the multi-layer reflective film 11 or the like. When seen in a plan view (Z-axis direction), the size of the substrate 10 is, for example, 152 mm long and 152 mm wide. The longitudinal dimension and the lateral dimension may be 152 mm or more. The first main surface 10a and the second main surface 10b each have a quality assurance area, for example, square, in the center. The size of the quality assurance area is, for example, 142 mm long and 142 mm wide. The longitudinal dimension and the lateral dimension may be 142 mm or more. The quality assurance area of the first main surface 10a may have a root mean square roughness (Rq) of 0.15 nm or less and a flatness of 100 nm or less. In addition, it is preferable that the quality assurance area of the first main surface 10a do not have disadvantages that cause phase defects.

The multi-layer reflective film 11 reflects EUV light. The multi-layer reflective film 11 is, for example, a laminate of high refractive index layers and low refractive index layers alternately. The material of the high refractive index layer is, for example, silicon (Si), the material of the low refractive index layer is, for example, molybdenum (Mo), and a Mo/Si multi-layer reflective film is used. Further, a Ru/Si multi-layer reflective film, a Mo/Be multi-layer reflective film, a Mo compound/Si compound multi-layer reflective film, a Si/Mo/Ru multi-layer reflective film, a Si/Mo/Ru/Mo multi-layer reflective film, a Si/Ru/Mo/Ru multi-layer reflective film, a Si/Ru/Mo multi-layer reflective film, or the like, is also usable as the multi-layer reflective film 11.

The film thickness of each layer constituting the multi-layer reflective film 11 and the number of repeating units of each layer can be selected appropriately depending on the material of each layer and its reflectance to EUV light. When the multi-layer reflective film 11 is the Mo/Si multi-layer reflective film, in order to achieve a reflectance of 60% or more for EUV light with an incidence angle θ (see FIG. 6) of 6°, a Mo layer with a film thickness of 2.3±0.1 nm and a Si layer with a film thickness of 4.5±0.1 nm should be laminated so that the repeating unit numbers are 30 or more and 60 or less. The multi-layer reflective film 11 preferably has a reflectance of 60% or more for EUV light when the incidence angle θ is 6°. The reflectance is more preferably 65% or more.

The film forming method of each layer that constitutes the multi-layer reflective film 11 is, for example, a DC sputtering method, a magnetron sputtering method, an ion beam sputtering method, or the like. When the Mo/Si multi-layer reflective film is formed using the ion beam sputtering method, examples of film forming conditions of the Mo layer and the Si layer are as follows.

### <Film Forming Conditions of Si Layer>

Target: Si target,
Sputter gas: Ar gas,
Gas pressure: 1.3×10⁻² Pa to 2.7×10⁻² Pa,
Ion acceleration voltage: 300 V to 1500 V,
Film forming speed: 0.030 nm/sec to 0.300 nm/sec,
Film thickness of Si layer: 4.5±0.1 nm

### <Film Forming Conditions of Mo Layer>

Target: Mo target,
Sputter gas: Ar gas,
Gas pressure: 1.3×10⁻² Pa to 2.7×10⁻² Pa,
Ion acceleration voltage: 300 V to 1500 V,
Film forming speed: 0.030 nm/sec to 0.300 nm/sec,
Film thickness of Mo layer: 2.3±0.1 nm

### <Repeating Unit of Si Layer and Mo Layer>

Repeating unit number: 30 to 60 (preferably, 40 to 50)

The protective film 12 is formed between the multi-layer reflective film 11 and the absorbing film 13, and protects the multi-layer reflective film 11. The protective film 12 protects the multi-layer reflective film 11 from the first etching gas during the processing of the absorbing film 13, i.e., step S203. The protective film 12 is not removed by the exposure to the first etching gas, but remains on top of the multi-layer reflective film 11.

The protective film 12 contains at least one element selected from, for example, Ru, Rh and Si. When the protective film 12 contains Rh, it may contain only Rh or may contain an Rh compound. The Rh compound may contain, in addition to Rh, at least one element Z1 selected from Ru, Nb, Mo, Ta, Ir, Pd, Zr, Y and Ti.

By adding Ru, Nb, Mo, Zr, Y or Ti to Rh, it is possible to suppress an increase in the refractive index while reducing the extinction coefficient, and to suppress the absorption of EUV light by the protective film 12 (and thus the decrease in reflectance to EUV light). In addition, by adding Ta, Ir, Pd or Y to Rh, it is possible to improve resistance to the first etching gas.

The Rh compound may contain at least one element Z2 selected from N, O, C and B, in addition to Rh. The element Z2 reduces the resistance of the protective film 12 to the first etching gas, but at the same time, it improves the smoothness of the protective film 12 by reducing the crystallinity of the protective film 12. The Rh compound containing the element Z2 has an amorphous structure or a microcrystalline structure. When the Rh compound has the amorphous structure or the microcrystalline structure, an X-ray diffraction profile of the Rh compound does not have a clear peak.

The protective film 12 may be a film constituted by a single layer, or may be a multi-layer film having a lower layer and an upper layer. The lower layer and the upper layer that constitute the protective film 12 are formed on the multi-layer reflective film 11 in that order. The lower layer of the protective film 12 is a layer formed in contact with the top surface of the multi-layer reflective film 11. The upper layer of the protective film 12 is in contact with the bottom surface of the absorbing film 13. In this way, by making the protective film 12 a multi-layer structure, materials with excellent predetermined functions can be used for each layer, thereby achieving multifunctionality for the entire protective film 12.

The upper layer of the protective film 12 preferably contains at least one element selected from Ru and Rh, more preferably contains Rh, and even more preferably contains an Rh compound. The lower layer of the protective film 12 preferably contains at least one element selected from Ru, Rh, Nb, Mo, Zr, Y, Si, C, N and B, and more preferably contains Ru. When the protective film 12 is the multi-layer film, the thickness of the protective film 12 described below means a total film thickness of the multi-layer film. Further, a mixed layer formed by mixing the component contained in the multi-layer reflective film 11 and the component contained in the lower layer of the protective film 12 may be formed between the multi-layer reflective film 11 and the lower layer of the protective film 12.

The thickness of the protective film 12 is preferably 1.0 nm to 4.0 nm, more preferably 2.0 nm to 3.5 nm, and further preferably 2.5 nm to 3.0 nm. When the thickness of the protective film 12 is 1.0 nm or more, the etching resistance becomes good. In addition, when the thickness of the protective film 12 is 4.0 nm or less, the reflectance to the EUV light becomes good.

A density of the protective film 12 is preferably 10.0 g/cm³ to 14.0 g/cm³. When the density of the protective film 12 is 10.0 g/cm³ or more, the etching resistance becomes good. In addition, when the density of the protective film 12 is 14.0 g/cm³ or less, a decrease in the reflectance to the EUV light can be minimized.

The upper surface of the protective film 12, i.e., a surface of the protective film 12 on which the absorbing film 13 is formed has, a root mean square roughness Rq of preferably 0.20 nm or less, and more preferably 0.17 nm or less. When the root mean square roughness Rq is 0.20 nm or less, the absorbing film 13 or the like can be formed smoothly on the protective film 12. In addition, it is possible to suppress scattering of the EUV light and improve the reflectance to the EUV light. The root mean square roughness Rq is preferably 0.05 nm or more.

The film forming method of the protective film 12 is, for example, a DC sputtering method, a magnetron sputtering method, an ion beam sputtering method, or the like. When the Rh film is formed using the DC sputtering method, an example of film forming conditions is as follows.

### <Film Forming Conditions of Rh Film>

Target: Rh target,
Sputter gas: Ar gas,
Gas pressure: 1.0×10⁻² Pa to 1.0×10⁰ Pa,
Output density of target: 1.0 W/cm² to 8.5 W/cm²,
Film forming speed: 0.020 nm/sec to 1.000 nm/sec,
Film thickness: 1 nm to 10 nm

The absorbing film 13 absorbs EUV light. The absorbing film 13 is a predetermined film on which the opening pattern 13a is formed. The opening pattern 13a is not formed in the manufacturing process of the reflective mask blank 1, but is formed in the manufacturing process of the reflective mask 2. The absorbing film 13 not only absorbs EUV light, but may also shift the phase of the EUV light. That is, the absorbing film 13 may be a phase shift film. The phase shift film shifts a phase of second EUV light L2 with respect to first EUV light L1 shown in FIG. 6.

The first EUV light L1 is light that passes through the opening pattern 13a without passing through the absorbing film 13, is reflected by the multi-layer reflective film 11, and passes through the opening pattern 13a again without passing through the absorbing film 13. The second EUV light L2 is light that passes through the absorbing film 13 while being absorbed by the absorbing film 13, is reflected by the multi-layer reflective film 11, and passing through the absorbing film 13 while being absorbed by the absorbing film 13 again.

A phase difference (≥0) between the first EUV light L1 and the second EUV light L2 is, for example, 170° to 250°. The phase of the first EUV light L1 may be ahead of or behind the phase of the second EUV light L2. The absorbing film 13 improves contrast of the transferred image using interference between the first EUV light L1 and the second EUV light L2. The transferred image is the image of the opening pattern 13a of the absorbing film 13 transferred to the target substrate.

In the EUVL, a so-called projection effect (shadowing effect) occurs. The shadowing effect refers to the occurrence of an area near the sidewall of the opening pattern 13a where the sidewall blocks the EUV light due to the incidence angle θ of the EUV light not being 0° (for example,) 6°, resulting in misalignment or dimensional deviation of the transferred image. In order to reduce the shadowing effect, it is effective to reduce the height of the sidewalls of the opening pattern 13a, and to make the absorbing film 13 thinner.

The film thickness of the absorbing film 13 is, for example, 60 nm or less, preferably 50 nm or less, in order to reduce the shadowing effect. The film thickness of the absorbing film 13 is preferably 20 nm or more and more preferably 30 nm or more, in order to secure the phase difference between the first EUV light L1 and the second EUV light L2.

In order to reduce the thickness of the absorbing film 13 to reduce the shadowing effect while maintaining the phase difference between the first EUV light L1 and the second EUV light L2, it is effective to reduce a refractive index n of the absorbing film 13. In addition, increasing the extinction coefficient k of the absorbing film 13 is effective in reducing the reflectance of the EUV light. In this way, the absorbing film 13 is required to have excellent optical characteristics.

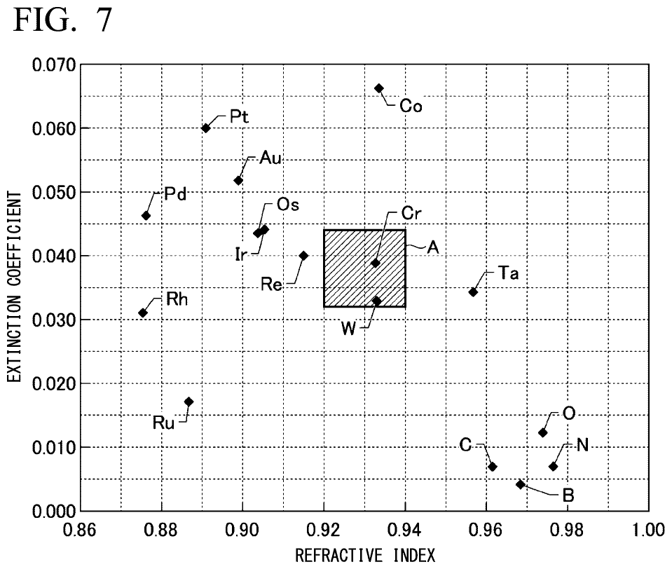

FIG. 7 is a view showing an example of the refractive index n and the extinction coefficient k of each element. In the specification, the refractive index n is the refractive index for EUV light (for example, light with a wavelength of 13.5 nm). In addition, in the specification, the extinction coefficient k is the extinction coefficient for EUV light (for example, light with a wavelength of 13.5 nm).

In FIG. 7, A is the range where the refractive index n is 0.920 to 0.940 and the extinction coefficient k is 0.032 to 0.044. Materials with Cr as the main component are considered to have optical characteristics in the range A. In the embodiment, as the material having the optical characteristics in the range A, a CrN compound containing 50 at % or more of Cr and 10 at % or more of N is used

The optical characteristics of the CrN compound (the refractive index n and the extinction coefficient k) are taken from the database of the Center for X-Ray Optics, Lawrence Berkeley National Laboratory, or values calculated from the “incidence angle dependence” of the reflectance, which will be described later.

The incidence angle θ of the EUV light, the reflectance R for the EUV light, the refractive index n of the absorbing film 13, and the extinction coefficient k of the absorbing film 13 satisfy the following equation (1):

$$R = \vert ( sin θ - {( {( n + i k )}^{2} - {cos}^{2} θ )}^{1 / 2} ) / ( sin θ + {( {( n + i k )}^{2} - {cos}^{2} θ )}^{1 / 2} ) \vert \qquad ( 1 )$$

Multiple combinations of the incidence angle θ and the reflectance R are measured, and the refractive index n and the extinction coefficient k are calculated using the least squares method so that the error between the plurality of measurement data and equation (1) is minimized.

The refractive index n of the CrN compound is preferably 0.920 to 0.940, more preferably 0.920 to 0.930. As the refractive index n of the absorbing film 13 is reduced, the absorbing film 13 can be thinned.

The extinction coefficient k of the CrN compound is preferably 0.032 to 0.044, more preferably 0.034 to 0.044. As the extinction coefficient k of the absorbing film 13 is increased, a relative reflectance Ra (to be described below) is reduced.

The relative reflectance Ra is a rate (%) of a reflectance R2 of the second EUV light L2 with respect to a reflectance R1 of the first EUV light L1. The first EUV light L1 is EUV light reflected by the multi-layer reflective film 11 and the protective film 12 to a side opposite to the substrate 10 without passing through the absorbing film 13. The reflectance R1 of the first EUV light L1 is measured, for example, before forming the absorbing film 13. The reflectance R1 of the first EUV light L1 may be measured after the absorbing film 13 was formed and removed. The second EUV light L2 is EUV light reflected by the multi-layer reflective film 11 and the protective film 12 to a side opposite to the substrate 10 via the absorbing film 13. The reflectance R2 of the second EUV light L2 is measured, for example, after the absorbing film 13 was formed.

The absorbing film 13 has a Cr-containing layer 13A consisting of a CrN compound. When the CrN compound has an N content of 10 at % or more, it has good amorphous properties and the relative reflectance Ra is less than 5%. When the relative reflectance Ra is less than 5%, it is possible to improve the intensity difference between the first EUV light L1 and the second EUV light L2 and improve contrast of the transferred image. The CrN compound preferably has an N content of 10 at % or more, more preferably 15 at % or more. The CrN compound preferably has an N content of 40 at % or less, more preferably 35 at % or less, further preferably 30 at % or less.

The amorphous property is expressed by diffraction line intensity of XRD using Cuk α rays. The CrN compound has a full width at half maximum FWHM of 1.0° or more of the peak with the highest intensity in the 2θ range of 20° to 50° measured by XRD using CuK α rays. An out-of-plane method is used for XRD.

When the full width at half maximum FWHM is 1.0° or more, it is possible to decrease crystallinity of the Cr-containing layer 13A and reduce the roughness of the sidewall of the opening pattern 13a. The full width at half maximum FWHM is preferably 2.0° or more, more preferably 3.0° or more. It is preferable that the full width at half maximum FWHM becomes larger and there is no clear peak.

As described above, the CrN compound contains 50 at % or more of Cr and 10 at % or more of N. The CrN compound preferably further contains Ru. The Ru content of the CrN compound is preferably 5 at % or more, more preferably 10 at % or more. When the Ru content of the CrN compound is 5 at % or more, the refractive index of the CrN compound is sufficiently small.

The Ru content of the CrN compound is preferably 25 at % or less. When the Ru content of the CrN compound is 25 at % or less, the extinction coefficient k of the CrN compound is 0.032 or more. The Ru content of the CrN compound is more preferably 20 at % or less.

A ratio (Ru/Cr) of the Ru content with respect to the Cr content of the CrN compound is preferably 0.60 or less. When the ratio (Ru/Cr) of the Ru content with respect to the Cr content of the CrN compound is 0.60 or less, the extinction coefficient k of the CrN compound is 0.032 or more. The ratio (Ru/Cr) of the Ru content with respect to the Cr content of the CrN compound is more preferably 0.50 or less, further preferably 0.40 or less, further more preferably 0.30 or less, particularly preferably 0.25 or less, most preferably 0.22 or less.

The absorbing film 13 may have an oxide layer 13B made of oxide on the side opposite to the protective film 12 relative to the Cr-containing layer 13A. The oxide layer 13B is formed, for example, by the natural oxidation of the surface of the Cr-containing layer 13A by the atmosphere. Further, the oxide layer 13B may be omitted, and the absorbing film 13 may by constituted by only the Cr-containing layer 13A. The thickness of the oxide layer 13B is preferably 5 nm or less. Since the thickness of the oxide layer 13B is sufficiently small, physical properties (for example, optical characteristics or the like) of the absorbing film 13 are substantially equal to physical properties of the Cr-containing layer 13A. The thickness of the oxide layer 13B is more preferably 4 nm or less. The thickness of the oxide layer 13B is preferably 0.1 nm or more.

The film forming method of the absorbing film 13 is, for example, a DC sputtering method, a magnetron sputtering method, an ion beam sputtering method, or the like. The nitrogen content of the absorbing film 13 can be controlled by the N₂ gas content in the sputter gas. Further, the oxygen content of the absorbing film 13 can be controlled by the O₂ gas content in the sputter gas.

When the RuCrN film is formed using the reactive sputtering method, an example of film forming conditions is as follows.

### <Film Forming Conditions of RuCrN Film>

Target: Ru target and Cr target,
Output density of Ru target: 1.0 W/cm² to 8.5 W/cm²,
Output density of Cr target: 1.0 W/cm² to 8.5 W/cm²,
Sputter gas: mixed gas of Ar gas and N₂ gas,
Volume ratio (N₂/(Ar+N₂)) of N₂ gas in sputter gas: 0.01 to 0.25,
Film forming speed: 0.020 nm/sec to 0.060 nm/sec,
Film thickness: 20 nm to 60 nm

The hard mask film 14 is formed on the opposite side of the absorbing film 13 from the protective film 12 and is used to form the opening pattern 13a in the absorbing film 13. The hard mask film 14 allows the resist film 16 to be made thinner.

The hard mask film 14 preferably contains at least one element selected from Al, Hf, Y, Cr, Nb, Ti, Mo, Ta and Si. The hard mask film 14 may further contain at least one element selected from O, N, C and B.

The film thickness of the hard mask film 14 is preferably 2 nm or more and 30 nm or less, more preferably 2 nm or more and 25 nm or less, further preferably 2 nm or more and 10 nm or less.

The film forming method of the hard mask film 14 is, for example, a DC sputtering method, a magnetron sputtering method, an ion beam sputtering method, or the like.

### EXAMPLES

Hereinafter, experimental data will be described. In Example 1 to Example 7, the reflective mask blank 1 having the substrate 10, the multi-layer reflective film 11, the protective film 12 and the absorbing film 13 in that order was fabricated. In Example 1 to Example 7, the reflective mask blank 1 was fabricated with the same configuration except for the configuration of the absorbing film 13. Example 1 to Example 3 are examples, and Example 4 to Example 7 are comparative examples.

As the substrate 10, a SiO₂—TiO₂ glass substrate (6-inch (152 mm) square, 6.3 mm thick) was prepared. The glass substrate had a thermal expansion coefficient of 0.02×10⁻7/° C. at 20° C., a Young's modulus of 67 GPa, a Poisson's ratio of 0.17, and a specific stiffness of 3.07×10⁷ m²/s². The quality assurance area of the first main surface 10a of the substrate 10 had a root mean square roughness (Rq) of 0.15 nm or less and a flatness of 100 nm or less after polishing. A 100 nm thick Cr film was formed on the second main surface 10b of the substrate 10 using the magnetron sputtering method. The sheet resistance of the Cr film was 100 Ω/□

As the multi-layer reflective film 11, a Mo/Si multi-layer reflective film was formed. The Mo/Si multi-layer reflective film was fabricated by repeating the process of forming a Si layer (film thickness 4.5 nm) and a Mo layer (film thickness 2.3 nm) 40 times using the ion beam sputtering method. A total film thickness of the Mo/Si multi-layer reflective film was 272 nm ((4.5 nm+2.3 nm)×40).

As the protective film 12, the Rh film (film thickness 5 nm) was formed. The Rh film was formed using the ion beam sputtering method.

As the absorbing film 13, a Cr-containing layer shown in Table 1 was formed. The Cr-containing layer was formed using a dual sputtering method. The chemical composition of the Cr-containing layer was measured using an X-ray photoelectron spectrometer (PHI 5000 VersaProbe) manufactured by ULVAC-PHI Corporation. The thickness of the Cr-containing layer and the oxide layer was measured by an X-ray reflectance (X-Ray reflectivity) method. The surface of the Cr-containing layer was naturally oxidized in the atmosphere to form an oxide layer, the thickness of which was 5 nm or less.

The experimental conditions and results for Examples 1 to 7 are shown in Table 1. Further, the relative reflectance Ra was calculated by calculating the reflectances R1 and R2 using the optical simulation described in Experimental Approach to EUV

Imaging Enhancement by Mask Absorber Height Optimization (2013) (authors: N. Davydova, R. Kruif, H. Rolff, B. Connolly, E. Setten, A. Lammers, D. Oorschot, N. Fukugami, Y. Kodera). Further, the thickness of the oxide layer is small enough that the relative reflectance Ra remains almost the same even with the oxide layer.

TABLE 1

| | Lower layer (Cr-containing layer) | | | | | | | | | Upper layer |
|---|---|---|---|---|---|---|---|---|---|---|
| | Ru- | Cr- | N- | | | | | | | (oxide layer) |
| | containing | containing | containing | | | Relative | | | Film | Film |
| | layer | layer | layer | | FWHM | reflectance | | | thickness | thickness |
| | [at %] | [at %] | [at %] | Ru/Cr | [°] | [%] | n | k | [nm] | [nm] |
| Example 1 | 15 | 73 | 12 | 0.21 | 5.60 | 1.8 | 0.923 | 0.036 | 48 | 0.4 |
| Example 2 | 15 | 62 | 23 | 0.24 | 4.94 | 2.1 | 0.923 | 0.035 | 48 | 0.1 |
| Example 3 | 0 | 74 | 26 | 0.00 | 7.64 | 0.7 | 0.927 | 0.038 | 55 | 0.9 |
| Example 4 | 51 | 35 | 14 | 1.46 | 2.42 | 6.0 | 0.909 | 0.025 | 49 | 0.6 |
| Example 5 | 0 | 92 | 8 | 0.00 | 0.85 | 0.8 | 0.929 | 0.037 | 55 | 0.1 |
| Example 6 | 18 | 82 | 0 | 0.22 | 0.60 | 1.8 | 0.922 | 0.036 | 48 | 0.6 |
| Example 7 | 15 | 77 | 8 | 0.19 | 0.90 | 0.8 | 0.929 | 0.037 | 55 | 1.4 |

As shown in Table 1, in Examples 1 to 3, unlike Examples 4 to 7, the Cr-containing layer was composed of a CrN compound containing 50 at % or more of Cr and 10 at % or more of N. As a result, in Examples 1 to 3, absorbing films with refractive indices of 0.920 to 0.940 and extinction coefficients of 0.032 to 0.044 were obtained, with good amorphous properties and relative reflectances of less than 5%.

Hereinabove, while the reflective mask blank, the reflective mask, the method of manufacturing the reflective mask blank, and the method of manufacturing the reflective mask according to the present disclosure have been described, the present disclosure is not limited to the embodiment or the like. Various changes, modifications, substitutions, additions, deletions, and combinations are possible within the scope of the claims. These naturally fall within the technical scope of the present disclosure.

Priority is claimed on Japanese Patent Application No. 2023-090180, filed May 31, 2023, the content of which is incorporated herein by reference.

### REFERENCE SIGNS LIST

1 Reflective mask blank
2 Reflective mask
10 Substrate
11 Multi-layer reflective film
12 Protective film
13 Absorbing film

1. A reflective mask blank containing a substrate, a multi-layer reflective film, a protective film, and an absorbing film, in that order,
wherein the multi-layer reflective film reflects EUV light, the protective film protects the multi-layer reflective film during processing of the absorbing film, and the absorbing film absorbs EUV light,
the absorbing film has a Cr-containing layer consisting of a CrN compound containing 50 at % or more of Cr and 10 at % or more of N, and
the Cr-containing layer has:
a full width at half maximum of 1.0° or more of the highest intensity peak in the 2θ range of 20° to 50° measured by XRD using CuK α rays, and
a rate of a reflectance of EUV light reflected by the multi-layer reflective film and the protective film toward the opposite side of the substrate via the absorbing film is less than 5% of a reflectance of EUV light reflected by the multi-layer reflective film and the protective film toward the opposite side of the substrate without passing through the absorbing film.

2. The reflective mask blank according to claim 1, wherein the CrN compound further contains Ru and a Ru content of the CrN compound is 25 at % or less, and
an extinction coefficient of the Cr-containing layer is 0.032 or more.

3. The reflective mask blank according to claim 1, wherein a refractive index of the Cr-containing layer is 0.920 or more and 0.940 or less.

4. The reflective mask blank according to claim 1, wherein a thickness of the Cr-containing layer is 20 nm to 60 nm.

5. The reflective mask blank according to claim 1, wherein the absorbing film has an oxide layer on the opposite side of the protective film from the Cr-containing layer, and
the thickness of the oxide layer is 5 nm or less.

6. The reflective mask blank according to claim 1, wherein the protective film contains at least one element selected from Ru, Rh and Si.

7. A reflective mask provided with the reflective mask blank according to claim 1, wherein an opening pattern is provided on the absorbing film.

8. A method of manufacturing a reflective mask blank, the method comprising forming a multi-layer reflective film, a protective film and an absorbing film on a substrate in that order,
wherein the multi-layer reflective film reflects EUV light, the protective film protects the multi-layer reflective film during processing of the absorbing film, and the absorbing film absorbs EUV light,
the absorbing film has a Cr-containing layer consisting of a CrN compound containing 50 at % or more of Cr and 10 at % or more of N, and
the Cr-containing layer has:
a full width at half maximum of 1.0° or more of the highest intensity peak in the 2θ range of 20° to 50° measured by XRD using Cuk α rays, and
a rate of a reflectance of EUV light reflected by the multi-layer reflective film and the protective film toward the opposite side of the substrate via the absorbing film is less than 5% of a reflectance of EUV light reflected by the multi-layer reflective film and the protective film toward the opposite side of the substrate without passing through the absorbing film.

9. A method of manufacturing a reflective mask, the method comprising:
preparing the reflective mask blank according to claim 1; and
forming an opening pattern on the absorbing film,
in that order.
